(19) United States
(12) Patent Application Publication
(10) Pub. No.: US 2023/0378272 A1
(43) Pub. Date: Nov. 23, 2023

(54) SEMICONDUCTOR DEVICE AND METHOD OF MANUFACTURING THE SAME

(71) Applicant: ROHM CO., LTD., Kyoto (JP)

(72) Inventor: Takeshi ISHIDA, Kyoto (JP)

(73) Assignee: ROHM CO., LTD., Kyoto (JP)

(21) Appl. No.: 18/315,943

(22) Filed: May 11, 2023

(30) Foreign Application Priority Data
May 20, 2022 (JP) 2022-083273

(51) Int. Cl. H01L 29/10; H01L 29/78; H01L 21/74; H01L 29/66

(52) U.S. Cl. CPC H01L 29/1083; H01L 29/7816; H01L 21/74; H01L 29/66681

(57) ABSTRACT

A semiconductor device includes: a base including a p-type substrate, an n-type semiconductor layer formed on the p-type substrate, and an element region having a transistor provided with a source region and a drain region, which are formed at an interval in a surface layer portion of the n-type semiconductor layer; and a p-type element isolation region formed in a surface layer portion of the base so as to partition the element region, and having an endless shape in a plan view, wherein the n-type semiconductor layer in the element region has a property that an n-type impurity concentration increases stepwise or continuously from a surface of the n-type semiconductor layer toward the p-type substrate over an entire region along a surface of the p-type substrate.

### CROSS-REFERENCE TO RELATED APPLICATION

This application is based upon and claims the benefit of priority from Japanese Patent Application No. 2022-083273, filed on May 20, 2022, the entire contents of which are incorporated herein by reference.

### TECHNICAL FIELD

The present disclosure relates to a semiconductor device and a method of manufacturing the same.

### BACKGROUND

In the related art, a semiconductor device, which includes a p-type isolation region for isolating an element region and a DMOS (Diffused Metal Oxide Semiconductor) transistor formed in the element region, has been disclosed. The semiconductor device includes a p-type semiconductor substrate and an n-type epitaxial layer (n-type semiconductor layer) formed on the p-type semiconductor substrate. In the element region, an n-type buried layer having an n-type impurity concentration higher than that of the n-type epitaxial layer is selectively formed across a boundary between the p-type semiconductor substrate and the n-type epitaxial layer. A p-type well region and an n-type well region are formed spaced apart from each other in the surface layer portion of the n-type epitaxial layer. An n-type source region is formed in the surface layer portion of the p-type well region, and an n-type drain region is formed in the surface layer portion of the n-type well region.

The n-type buried layer is formed by increasing the impurity concentration of a base region of a parasitic pnp type transistor, which is formed by the p-type well region, the n-type epitaxial layer (the n-type buried layer), and the p-type semiconductor substrate, so as to suppress the operation of the parasitic pnp type transistor.

As disclosed in related art, in the semiconductor device in which the n-type buried layer is selectively formed in the element region, isolation between the transistor and the p-type semiconductor substrate is done by a parasitic pn diode formed by the p-type semiconductor substrate and the n-type buried layer. However, the n-type impurity concentration of the n-type buried layer is much higher than that of the n-type epitaxial layer due to the manufacturing method of the n-type buried layer. As a result, the breakdown voltage of the parasitic pn diode is lowered, so that the breakdown voltage of the transistor is lowered.

Therefore, there is a method of insulating and isolating the n-type epitaxial layer and the p-type semiconductor substrate using an SOI substrate, but the manufacturing cost increases because the SOI substrate is expensive.

Further, as the p-type semiconductor substrate, by using a p-type semiconductor substrate with a low p-type impurity concentration, it is conceivable to increase the breakdown voltage of the parasitic pn diode formed by the p-type semiconductor substrate and the n-type buried layer. However, when another element other than the DMOS transistor is formed on the same substrate, a parasitic npn transistor, which is formed by an n-type epitaxial layer of the DMOS transistor, an n-type epitaxial layer of the another element adjacent thereto, and the p-type semiconductor substrate therebetween, is likely to activate easily.

### SUMMARY

Some embodiments of the present disclosure provide a semiconductor device capable of increasing the breakdown voltage of a transistor, and a method of manufacturing the same.

According to one embodiment of the present disclosure, a semiconductor device includes: a base including a p-type substrate, an n-type semiconductor layer formed on the p-type substrate, and an element region having a transistor provided with a source region and a drain region, which are formed at an interval in a surface layer portion of the n-type semiconductor layer; and a p-type element isolation region formed in a surface layer portion of the base so as to partition the element region, and having an endless shape in a plan view, wherein the n-type semiconductor layer in the element region has a property that an n-type impurity concentration increases stepwise or continuously from a surface of the n-type semiconductor layer toward the p-type substrate over an entire region along a surface of the p-type substrate.

With this configuration, it is possible to increase the breakdown voltage of a transistor. According to another embodiment of the present disclosure, a method of manufacturing a semiconductor device includes: forming a base including a p-type substrate and an n-type semiconductor layer formed on the p-type substrate and having a property that an n-type impurity concentration increases stepwise or continuously from a surface of the n-type semiconductor layer toward the p-type substrate by allowing a semiconductor to epitaxially grow while adding n-type impurities to a surface of the p-type substrate; forming an element region, which is surrounded by a p-type element isolation region, in the base by forming the p-type element isolation region, which reaches the p-type substrate from a surface of the n-type semiconductor layer and has an endless shape in a plan view, in the base; and forming a source region and a drain region at an interval in a surface layer portion of the n-type semiconductor layer in the element region.

With this manufacturing method, it is possible to manufacture a semiconductor element capable of increasing the breakdown voltage of a transistor.

### BRIEF DESCRIPTION OF DRAWINGS

The accompanying drawings, which are incorporated in and constitute a part of the specification, illustrate embodiments of the present disclosure.

FIG. 1 is a schematic plan view for explaining a configuration of a semiconductor device according to a first embodiment of the present disclosure.

FIG. 2 is a schematic cross-sectional view taken along line II-II in FIG. 1.

FIG. 3 is a graph for explaining a concentration profile of a substrate.

FIG. 4A is a cross-sectional view showing an example of a process of manufacturing the semiconductor device shown in FIGS. 1 and 2, and corresponds to a cut section of FIG. 2.

FIG. 4B is a cross-sectional view showing a next step of FIG. 4A.

FIG. 4C is a cross-sectional view showing a next step of FIG. 4B.

FIG. 4D is a cross-sectional view showing a next step of FIG. 4C.

FIG. 4E is a cross-sectional view showing a next step of FIG. 4D.

FIG. 4F is a cross-sectional view showing a next step of FIG. 4E.

FIG. 4G is a cross-sectional view showing a next step of FIG. 4F.

FIG. 5 is a schematic cross-sectional view for explaining a configuration of a semiconductor device according to a second embodiment of the present disclosure.

FIG. 6 is a graph for explaining a concentration profile of a substrate.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of the present disclosure will be described in detail with reference to the accompanying drawings.

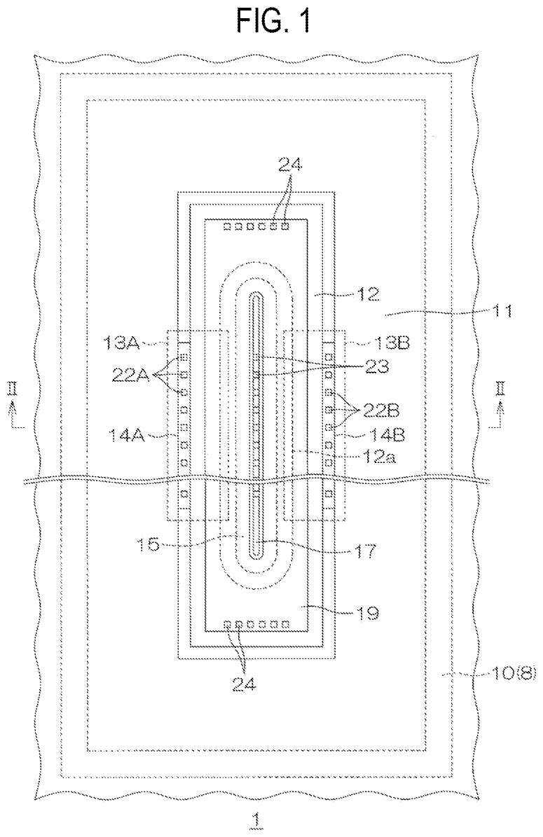

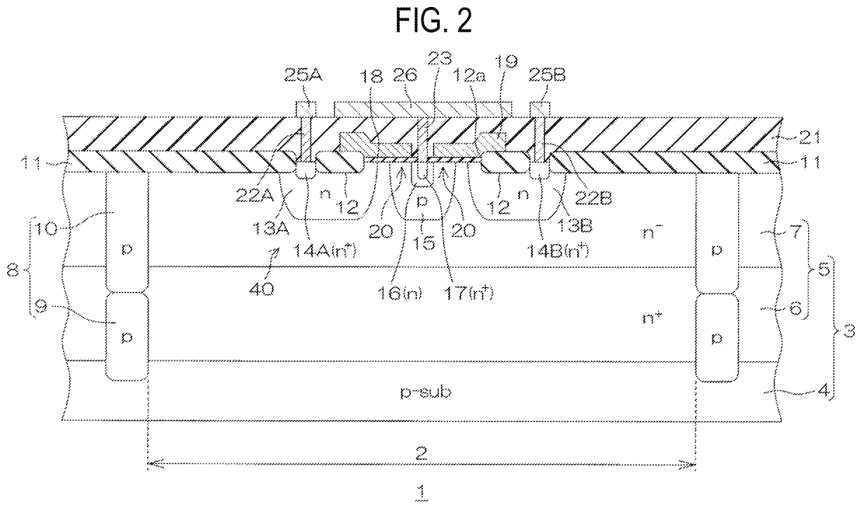

FIG. 1 is a schematic plan view for explaining a configuration of a semiconductor device according to a first embodiment of the present disclosure. FIG. 2 is a schematic cross-sectional view taken along line II-II in FIG. 1. An interlayer insulating film 21, drain wirings 25A and 25B, and a source wiring 26 shown in FIG. 2 are omitted in FIG. 1.

In the following, a left-right direction of the paper surface of FIG. 1 is referred to as a horizontal direction, and a top-bottom direction of the paper surface of FIG. 1 is referred to as a vertical direction.

The semiconductor device 1 includes a base 3. The base 3 includes a p-type semiconductor substrate 4 and an n-type epitaxial layer 5 formed on the p-type semiconductor substrate 4. In this embodiment, the p-type semiconductor substrate 4 is a silicon substrate. The p-type semiconductor substrate 4 is an example of the “p-type substrate” of the present disclosure, and the n-type epitaxial layer 5 is an example of the “n-type semiconductor layer” of the present disclosure.

A p-type element isolation region 8 that partitions an element region 2 is formed in the surface layer portion of the base 3. In this embodiment, the element region 2 has a quadrangular shape elongated in the vertical direction in a plan view. A DMOS transistor 40 is formed in the element region 2.

The p-type element isolation region 8 is an endless shape in a plan view. In this embodiment, the p-type element isolation region 8 has a rectangular annular shape in a plan view, but may have an endless shape such as an annular shape or an elliptical shape. The p-type element isolation region 8 penetrates the n-type epitaxial layer 5 from the surface of the n-type epitaxial layer 5 and reaches the mid-thickness portion of the p-type semiconductor substrate 4. The p-type element isolation region 8 includes a lower isolation region 9 connected to the p-type semiconductor substrate 4 and an upper isolation region 10 formed on the lower isolation region 9. The p-type element isolation region 8 may reach the p-type semiconductor substrate 4 from the surface of the n-type epitaxial layer 5.

The element region 2, which is formed by a portion of the n-type epitaxial layer 5 surrounded by the p-type element isolation region 8 on the p-type semiconductor substrate 4, is partitioned in the base 3. Although not shown, the p-type element isolation region 8 and the p-type semiconductor substrate 4 are grounded.

In this embodiment, the n-type epitaxial layer 5 includes an n⁺-type first region 6 of a lower side, which is in contact with the p-type semiconductor substrate 4, and an n⁻-type second region 7 of an upper side, which is formed on the first region 6 and has an n-type impurity concentration lower than that of the first region 6. The first region 6 covers the entire upper surface of the element region 2 in the p-type semiconductor substrate 4. The outer peripheral surface (side surface) of the first region 6 is in contact with the inner peripheral surface (inner side surface) of the p-type element isolation region 8. The outer peripheral surface (side surface) of the second region 7 is also in contact with the inner peripheral surface (inner side surface) of the p-type element isolation region 8.

The n-type impurity concentration of the first region 6 is preferably 3×10¹⁵ cm⁻³ or more and 1×10¹⁷ cm⁻³ or less. The reason why the n-type impurity concentration of the first region 6 is specifically 3×10¹⁵ cm⁻³ or more is that if the n-type impurity concentration of the first region 6 is less than 3×10¹⁵ cm⁻³, a parasitic pnp transistor, which is formed by a p-type well region 15 to be described later, the n-type epitaxial layer 5 (the first region 6), and the p-type semiconductor substrate 4, is likely to activate easily.

The reason why the n-type impurity concentration of the first region 6 is specifically 1×10¹⁷ cm⁻³ or less is that if the n-type impurity concentration of the first region 6 is higher than 1×10¹⁷ cm⁻³, the breakdown voltage of a parasitic pn diode, which is formed by the p-type semiconductor substrate 4 and the first region 6, is lowered and the breakdown voltage of the transistor 40 is lowered.

The n-type impurity concentration of the second region 7 is about 5×10¹⁴ cm⁻³ or more and 3×10¹⁵ cm⁻³ or less.

The film thickness of the n-type epitaxial layer 5 is, for example, about 3.0 μm to 15 μm. The film thickness of the first region 6 is specifically 3 μm or more, more specifically 4 μm or more. The film thickness of the first region 6 is specifically 3/10 or more, more specifically ⅖ or more, of the film thickness of the n-type epitaxial layer 5. This is because the breakdown voltage of the parasitic pn diode, which is formed by the p-type semiconductor substrate 4 and the first region 6, increases as the film thickness of the first region 6 increases.

In this embodiment, the n-type impurity concentration of the first region 6 is 5×10¹⁵ cm⁻³ and the n-type impurity concentration of the second region 7 is 1×10¹⁵ cm⁻³. The film thickness of the n-type epitaxial layer 5 is 10 μm, the film thickness of the first region 6 is 5 μm, and the film thickness of the second region 7 is 5 μm.

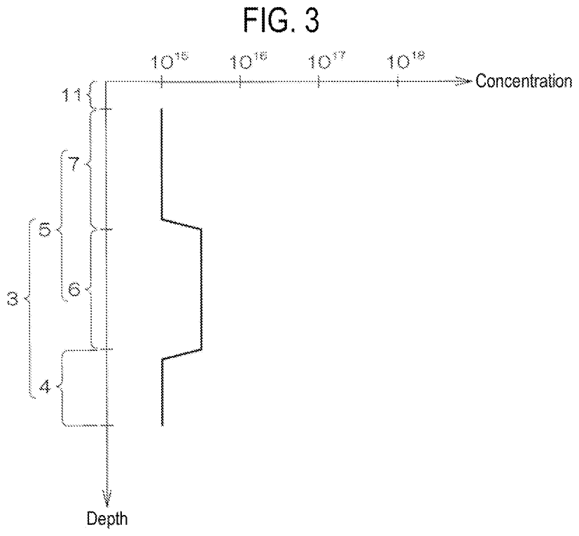

FIG. 3 is a graph for explaining a concentration profile of the base 3. As shown in FIG. 3, in the present embodiment, the n-type epitaxial layer 5 in the element region 2 has a property that the n-type impurity concentration increases stepwise from the surface of the n-type epitaxial layer 5 toward the p-type semiconductor substrate 4 over the entire region along the surface of the p-type semiconductor substrate 4. Specifically, in the second region 7, the n-type impurity concentration is a predetermined second impurity concentration, and in the first region 6, the n-type impurity concentration is a predetermined first impurity concentration higher than the second impurity concentration.

In the base 3, an element region (not shown) in which another element different from the DMOS transistor 40 in the element region 2 is formed is partitioned in the peripheral region of the element region 2.

A field insulating film 11 of an endless shape is formed on the surface of the p-type element isolation region 8 in a plan view. The field insulating film 11 is formed in a quadrangular annular shape so as to surround the central region of the element region 2 in a plan view. The field insulating film 11 is wider than the p-type element isolation region 8 and formed so as to completely cover the p-type element isolation region 8. The field insulating film 11 is, for example, a LOCOS film formed by selectively oxidizing the surface of the second region 7.

The DMOS transistor 40 includes two n-type drain regions (n-type well regions) 13A and 13B formed in the surface layer portion of the second region 7, and a p-type well region 15 formed in the surface layer portion of the second region 7. In this embodiment, the p-type well region 15 has a quadrangular shape elongated in the vertical direction in a plan view and is formed in the central portion of the element region 2 in the horizontal direction.

The two n-type drain regions 13A and 13B are arranged on both sides of the p-type well region 15 to be spaced apart from each other in a plan view. Hereinafter, one of the two n-type drain regions 13A and 13B may be referred to as a first n-type drain region 13A and the other may be referred to as a second n-type drain region 13B.

Each of the n-type drain regions 13A and 13B has a quadrangular shape elongated in the vertical direction in a plan view. Each of the n-type drain regions 13A and 13B has an impurity concentration higher than that of the n⁻-type second region 7. A first n⁺-type drain contact region 14A having an impurity concentration higher than that of the first n-type drain region 13A is formed in the surface layer portion of the first n-type drain region 13A. A second n⁺-type drain contact region 14B having an impurity concentration higher than that of the second n-type drain region 13B is formed in the surface layer portion of the second n-type drain region 13B.

An n-type source region 16 having an impurity concentration higher than that of the n⁻-type second region 7 is formed in the surface layer portion of the p-type well region 15. An n⁻-type source contact region 17 having an impurity concentration higher than that of the n-type source region 16 is formed in the surface layer portion of the n-type source region 16.

For example, the n-type source region 16 is formed with the same concentration as the n-type drain region 13. Further, for example, the n-type source region 16 is formed with substantially the same depth as the p-type well region 15. The outer peripheral edge of the n-type source region 16 is arranged at an interval inward from the outer peripheral edge of the p-type well region 15. The outer peripheral edge of the n⁺-type source contact region 17 is arranged at an interval inward from the outer peripheral edge of the n-type source region 16. For example, the n⁺-type source contact region 17 is formed with the same concentration and depth as the n⁺-type drain contact region 14.

A rectangular annular field insulating film 12, which is elongated in the vertical direction in a plan view, is formed on the surface of the second region 7 in a portion between the p-type well region 15 and the field insulating film 11. The field insulating film 12 is a LOCOS film formed in the same process as the above-described field insulating film 11. In FIG. 1, the inner peripheral edge of the field insulating film 12 is denoted by reference numeral 12a.

The inner peripheral edge of the field insulating film 12 is arranged at an interval outward from the outer peripheral edge of the p-type well region 15 in a plan view. The outer peripheral edge of the field insulating film 12 is arranged at an interval inward from the inner peripheral circle of the field insulating film 11 in a plan view. The first n⁺-type drain contact region 14A and the second n⁺-type drain contact region 14B are arranged in a region sandwiched between the outer peripheral edge of the field insulating film 12 and the inner peripheral edge of the field insulating film 11 in a plan view.

Further, a gate insulating film 18 is formed on the surface of the second region 7 in a region surrounded by the field insulating film 12 and excluding the n⁺-type source contact region 17. The gate insulating film 18 is formed in a quadrangular annular shape in a plan view so as to surround the n⁺-type source contact region 17. The gate insulating film 18 includes a portion arranged so as to straddle between the first n-type drain region 13A and the p-type well region 15 and a portion arranged so as to straddle between the second n-type drain region 13B and the p-type well region 15.

A gate electrode 19 is formed on the gate insulating film 18. The gate electrode 19 is formed in a quadrangular ring shape in a plan view so as to surround the n-type source region 16. The gate electrode 19 covers a region of the surface of the gate insulating film 18, which excludes the inner peripheral edge, and a region of the exposed surface of the field insulating film 12, which is near the inner peripheral edge of the field insulating film 12.

The gate electrode 19 is made of, for example, polysilicon. The gate insulating film 18 is, for example, a silicon oxide film formed by oxidizing the surface of the n-type epitaxial layer 5.

A region where the gate electrode 19 faces the p-type well region 15 via the gate insulating film 18 is a channel region 20 of the DMOS transistor 40. Formation of a channel in the channel region 20 is controlled by the gate electrode 19.

An interlayer insulating film 21 is formed to cover the entire element region 2. The interlayer insulating film 21 is formed of, for example, an insulating film such as an oxide film or a nitride film.

A plurality of first drain contact plugs 22A, a plurality of second drain contact plugs 22B, a plurality of source contact plugs 23, and a plurality of gate contact plugs 24 are buried in the interlayer insulating film 21.

The lower ends of the plurality of first drain contact plugs 22A are connected to the first n⁺-type drain contact region 14A. The lower ends of the plurality of second drain contact plugs 22B are connected to the second n⁺-type drain contact region 14B. The lower ends of the plurality of source contact plugs 23 are connected to the n⁺-type source contact region 17. The lower ends of the plurality of gate contact plugs 24 are connected to the gate electrode 19.

A first drain wiring 25A, a second drain wiring 25B, a source wiring 26, and a gate wiring (not shown) are formed on the interlayer insulating film 21. The first drain wiring 25A is electrically connected to the first n⁺-type drain contact region 14A via the plurality of first drain contact plugs 22A. The second drain wiring 25B is electrically connected to the second n⁺-type drain contact region 14B via the plurality of second drain contact plugs 22B.

The source wiring 26 is electrically connected to the n⁺-type source contact region 17 via the plurality of source contact plugs 23. The gate wiring is electrically connected to the gate electrode 19 via the plurality of gate contact plugs 24.

Although not shown in FIG. 1, the source wiring 26 has a quadrangular shape elongated in the vertical direction in a plan view and covers the mid-length portion between both ends of the gate electrode 19. A plurality of locations in the mid-width portion of the source wiring 26 is electrically connected to the n⁺-type source contact region 17 via the plurality of source contact plugs 23. The gate wiring is electrically connected to both ends of the gate electrode 19 via the plurality of gate contact plugs 24.

Although not shown in FIG. 1, the first drain wiring 25A has a quadrangular shape elongated in the vertical direction in a plan view and covers the first n-type drain contact region 14A. Although not shown in FIG. 1, the second drain wiring 25B has a quadrangular shape elongated in the vertical direction in a plan view and covers the second n-type drain contact region 14B.

In the semiconductor device disclosed in the related art, the n-type buried layer having an n-type impurity concentration higher than that of the n-type epitaxial layer is selectively formed in the element region so as to cross the boundary between the p-type semiconductor substrate and the n-type epitaxial layer. Such an n-type buried layer is formed, for example, as follows.

That is, after selectively implanting n-type impurities for forming the n-type buried layer into the surface of the p-type semiconductor substrate, a semiconductor is allowed to epitaxially grow on the p-type semiconductor substrate while adding the n-type impurities under a heating condition. During the epitaxial growth process, the n-type impurities, which are previously implanted into the p-type semiconductor substrate, diffuse in the growth direction of the epitaxial layer. As a result, the n-type buried layer is formed across the boundary between the p-type semiconductor substrate and the n-type epitaxial layer.

Since the n-type buried layer is formed in this manner, the n-type impurity concentration of the n-type buried layer is much higher than that of the n-type epitaxial layer. The n-type impurity concentration of the n-type epitaxial layer is, for example, about 1×10¹⁵ cm⁻³, whereas the n-type impurity concentration of the n-type buried layer is, for example, about 1×10¹⁸ cm⁻³. Therefore, the breakdown voltage of the parasitic pn diode, which is formed by the p-type semiconductor substrate and the n-type buried layer, is lowered, so that the element breakdown voltage of the DMOS transistor formed in the element region is also lowered.

If the n-type impurity concentration of the n-type buried layer is to be lowered, the thickness of the n-type buried layer becomes thin, so that the breakdown voltage of the parasitic pn diode, which is formed by the p-type semiconductor substrate and the n-type buried layer, is lowered.

In the semiconductor device 1 according to the first embodiment, the n-type semiconductor layer 5 in the element region 2 has a property that the n-type impurity concentration increases stepwise from the surface of the n-type semiconductor layer 5 toward the p-type semiconductor substrate 4 over the entire region along the surface of the p-type semiconductor substrate 4. Specifically, the n-type epitaxial layer 5 formed on the p-type semiconductor substrate 4 includes the lower n⁺-type first region 6 in contact with the p-type semiconductor substrate 4, and the upper n⁻-type second region 7 formed on the first region 6 and having a lower n-type impurity concentration than the first region 6.

As a result, it is possible to set the n-type impurity concentration of the first region 6 to be higher than the n-type impurity concentration of the second region 7 and lower than the n-type impurity concentration of the conventional n-type buried layer. As a result, the breakdown voltage of the parasitic pn diode formed by the p-type substrate and the first region 6 can be increased, so that it is possible to increase the element breakdown voltage of the DMOS transistor formed in the element region.

Further, in the semiconductor device 1 according to the first embodiment, it is possible to reduce the manufacturing cost as compared to a semiconductor device in which an SOI substrate is used to insulate and isolate an n-type epitaxial layer and a p-type substrate.

Further, in the semiconductor device 1 according to the first embodiment, it is not necessary to use a p-type semiconductor substrate having a low p-type impurity concentration in order to increase the breakdown voltage of the parasitic pn diode, so that it is possible to prevent a parasitic npn-type transistor, which is formed by the n-type epitaxial layer of the DMOS transistor, the n-type epitaxial layer of another element adjacent thereto, and the p-type semiconductor substrate therebetween, from activating easily.

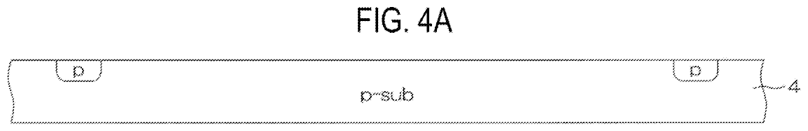

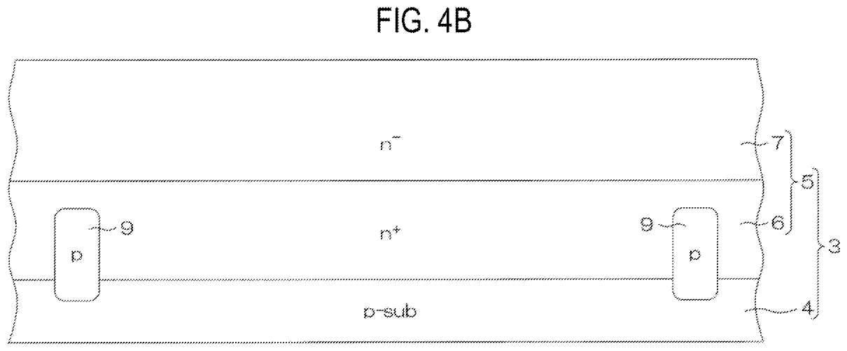

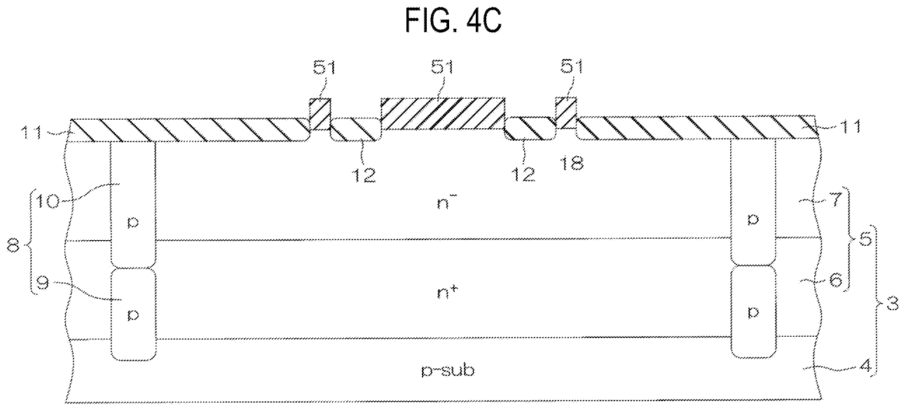

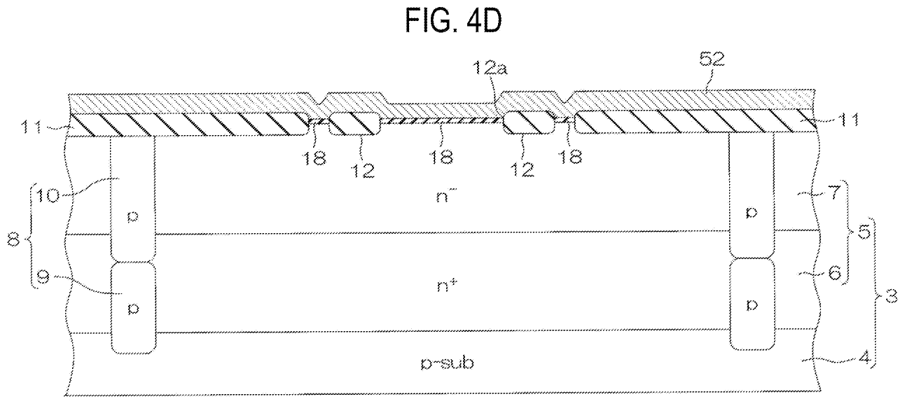

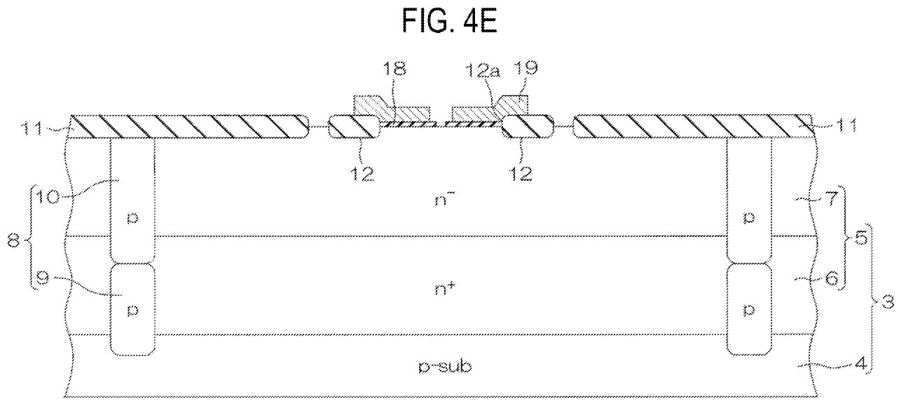

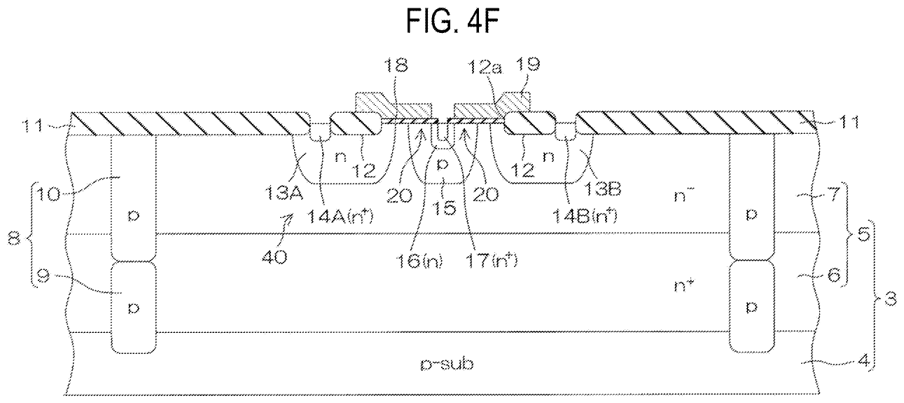

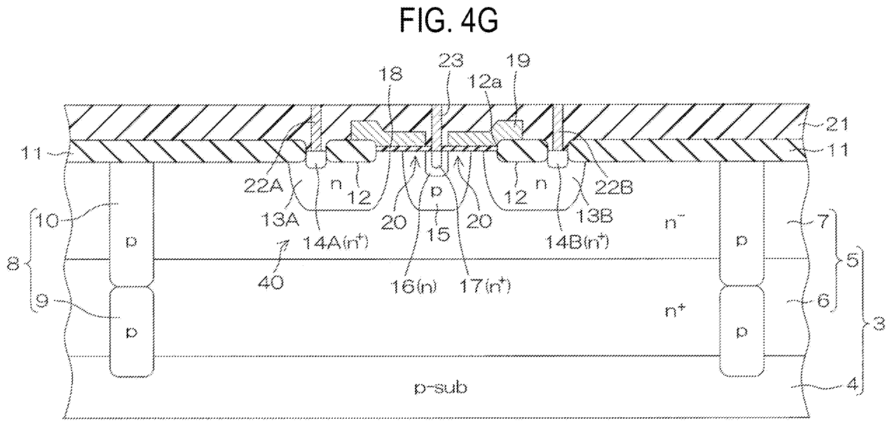

Next, a process of manufacturing the semiconductor device 1 will be described with reference to FIGS. 4A to 4G. FIGS. 4A to 4G are cross-sectional views for explaining an example of a process of manufacturing the semiconductor device 1, and correspond to the cut section of FIG. 2.

In order to manufacture the semiconductor device 1, a p-type semiconductor substrate 4 is prepared as shown in FIG. 4A. Next, p-type impurities are selectively implanted into the surface of the p-type semiconductor substrate 4. Then, under a heating condition of, for example, 1,100 degrees C. or higher, silicon is allowed to epitaxially grow on the p-type semiconductor substrate 4 while adding n-type impurities.

In the epitaxial growth, an addition amount of the n-type impurities is initially set such that the n-type impurity concentration becomes a predetermined first impurity concentration, and then is set such that the n-type impurity concentration becomes a predetermined second impurity concentration lower than the first impurity concentration. As a result, as shown in FIG. 4B, an n-type epitaxial layer 5, which is formed with an n⁺-type first region 6 having a high n-type impurity concentration and an n⁻-type second region 7 formed on the first region 6 and having an n-type impurity concentration lower than that of the first region 6, is formed on the p-type semiconductor substrate 4. Further, as a result, a base 3 including the p-type semiconductor substrate 4 and the n-type epitaxial layer 5 is formed.

During the epitaxial growth, the p-type impurities implanted into the p-type semiconductor substrate 4 diffuse in a growth direction of the n-type epitaxial layer 5. Thus, a p-type lower isolation region 9 is formed. Examples of the p-type impurities may include B (boron) and Al (aluminum), and examples of the n-type impurities may include P (phosphorus) and As (arsenic).

Next, as shown in FIG. 4C, an ion implantation mask (not shown) having selective openings in a region where a p-type upper isolation region 10 is to be formed is formed on the n-type epitaxial layer 5. Then, p-type impurities are implanted into the n-type epitaxial layer 5 through the ion implantation mask. Thus, a p-type element isolation region 8 having a two-layer structure of the lower isolation region 9 and the upper isolation region 10 is formed. After that, the ion implantation mask is removed.

Next, a hard mask 51 having selective openings in a region where field insulating films 11 and 12 are to be formed is formed on the n-type epitaxial layer 5. Then, the surface of the n-type epitaxial layer 5 is subjected to thermal oxidation through the hard mask 51 to form the field insulating films 11 and 12. After that, the hard mask 51 is removed.

Next, as shown in FIG. 4D, the surface of the n-type epitaxial layer 5 is subjected to thermal oxidation to form a gate insulating film 18. At this time, the gate insulating film 18 is formed so as to be continuous with the field insulating films 11 and 12. Next, polysilicon for a gate electrode 19 is deposited on the n-type epitaxial layer 5 to form a polysilicon layer 52.

Next, a resist mask (not shown) having selective openings in a region where the gate electrode 19 is to be formed is formed on the polysilicon layer 52. Then, an unnecessary portion of the polysilicon layer 52 is removed by etching through the resist mask. Thus, the gate electrode 19 is formed as shown in FIG. 4E. After that, the resist mask is removed.

Next, in order to remove an unnecessary portion of the gate insulating film 18, a hard mask (not shown) having selective openings is formed on the n-type epitaxial layer 5. Then, the unnecessary portion of the gate insulating film 18 is subjected to etching through the hard mask. Thus, a predetermined gate insulating film 18 is formed. After that, the hard mask is removed. The step of selectively etching the gate insulating film 18 may be omitted.

Next, as shown in FIG. 4F, a p-type well region 15 is formed in the surface layer portion of the n-type epitaxial layer 5. In order to form the p-type well region 15, first, an ion implantation mask (not shown) having selective openings in a region where the p-type well region 15 is to be formed is formed. Then, p-type impurities are implanted into the n-type epitaxial layer 5 through the ion implantation mask. After that, the p-type impurities are thermally diffused at a temperature of, for example, 900 degrees C. to 1,100 degrees C. Thus, the p-type well region 15 is formed. After that, the ion implantation mask is removed.

In the step before the gate insulating film 18 and the gate electrode 19 are formed (FIG. 4C), the p-type well region 15 may be formed by selectively implanting the p-type impurities into the n-type epitaxial layer 5.

Next, first and second n-type drain regions 13A and 13B are formed in the surface layer portion of the n-type epitaxial layer 5. In order to form the first and second n-type drain regions 13A and 13B, first, an ion implantation mask (not shown) having selective openings in a region where the first and second n-type drain regions 13A and 13B are to be formed is formed. Then, n-type impurities are implanted into the n-type epitaxial layer 5 through the ion implantation mask. Thus, the first and second n-type drain regions 13A and 13B are formed. After that, the ion implantation mask is removed.

Next, an n-type source region 16 is formed in the inner region (surface layer portion) of the p-type well region 15. In order to form the n-type source region 16, first, an ion implantation mask (not shown) having selective openings in a region where the n-type source region 16 is to be formed is formed. Then, n-type impurities are implanted into the n-type epitaxial layer 5 through the ion implantation mask. Thus, the n-type source region 16 is formed. After that, the ion implantation mask is removed.

Next, a first n⁺-type drain contact region 14A, a second n⁺-type drain contact region 14B, and an n⁺-type source contact region 17 are formed in the inner regions (surface layer portions) of the first n-type drain region 13A, the second n-type drain region 13B, and the n-type source region 16, respectively.

In order to form these contact regions 14A, 14B, and 17, first, an ion implantation mask (not shown) having selective openings in regions where the first n⁺-type drain contact region 14A, the second n⁺-type drain contact region 14B, and the n⁺-type source contact region 17 are to be formed, respectively, is formed. Then, n-type impurities are implanted into the first n-type drain region 13A, the second n-type drain region 13B, and the n-type source region 16 through the ion implantation mask. Thus, the first n⁺-type drain contact region 14A, the second n⁺-type drain contact region 14B, and the n⁺-type source contact region 17 are formed. After that, the ion implantation mask is removed.

Next, as shown in FIG. 4G, an interlayer insulating film 21 is formed by depositing an insulating material so as to cover the gate electrode 19. Next, a first drain contact plug 22A, a second drain contact plug 22B, a source contact plug 23, and a gate contact plug 24 are formed so as to penetrate the interlayer insulating film 21.

The first drain contact plug 22A, the second drain contact plug 22B, the source contact plug 23, and the gate contact plug 24 are electrically connected to a first n⁺-type source contact region 17A, a second n⁺-type source contact region 17B, the n⁺-type source contact region 17, and the gate electrode 19, respectively.

Finally, a first drain wiring 25A, a second drain wiring 25B, a source wiring 26, and a gate wiring (not shown), which are electrically connected to the first drain contact plug 22A, the second drain contact plug 22B, the source contact plug 23, and the gate contact plug 24, respectively, are selectively formed on the interlayer insulating film 21.

In order to form the first drain wiring 25A, the second drain wiring 25B, the source wiring 26, and the gate wiring, for example, a wiring material layer is formed on the interlayer insulating film 21. Then, the first drain wiring 25A, the second drain wiring 25B, the source wiring 26, and the gate wiring are formed by selectively removing the wiring material layer by photolithography and etching. Through the above steps, the semiconductor device 1 according to the first embodiment is manufactured.

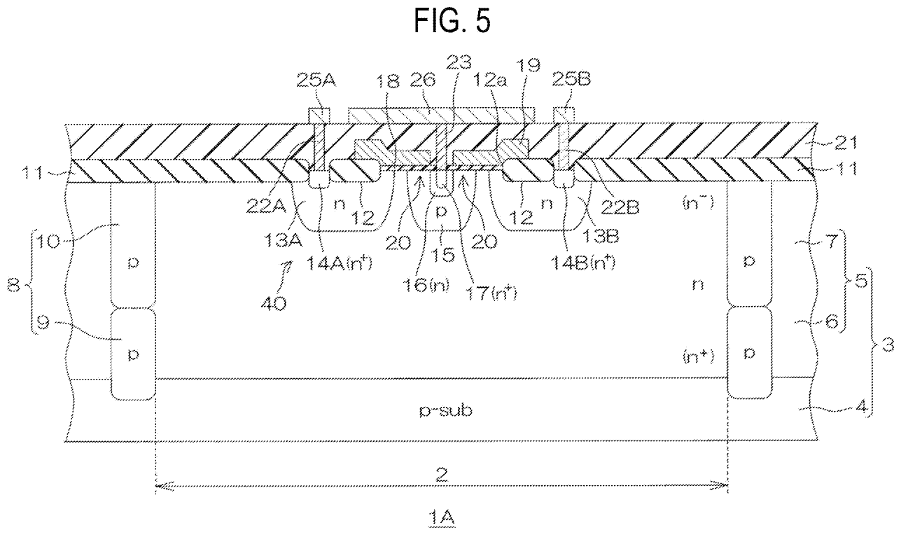

Next, a semiconductor device 1A according to a second embodiment of the present disclosure will be described with reference to FIG. 5.

FIG. 5 is a schematic cross-sectional view for explaining a configuration of the semiconductor device according to the second embodiment of the present disclosure, and corresponds to the cut section of FIG. 2. The plan view of the semiconductor device according to the second embodiment is the same as the plan view (see FIG. 1) of the semiconductor device according to the first embodiment. In FIG. 5, the parts corresponding to the parts in FIG. 2 are denoted by the same reference numerals as in FIG. 2.

The semiconductor device 1A according to the second embodiment is different from the semiconductor device 1 according to the first embodiment in terms of the structure of the n-type epitaxial layer 5, more specifically, the concentration profile of the n-type epitaxial layer 5. Other configurations are the same as those of the semiconductor device 1 according to the first embodiment.

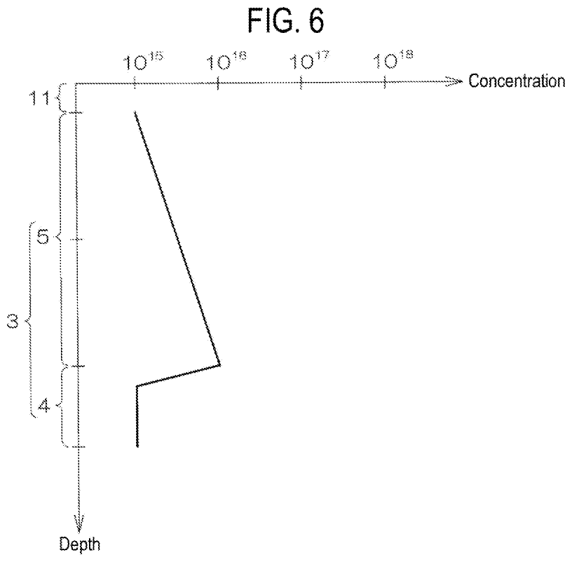

FIG. 6 is a graph for explaining a concentration profile of the base 3.

In the semiconductor device 1A according to the second embodiment, the n-type epitaxial layer 5 in the element region 2 has a property that the n-type impurity concentration increases continuously from the surface of the n-type epitaxial layer 5 toward the p-type semiconductor substrate 4 over the entire region along the surface of the p-type semiconductor substrate 4.

In other words, when the surface of the n-type epitaxial layer 5 on the p-type semiconductor substrate 4 side is the bottom surface and the surface of the n-type epitaxial layer 5 on the opposite side thereof is the top surface, the n-type epitaxial layer 5 in the element region 2 has a property that the n-type impurity concentration in the n-type epitaxial layer 5 increases continuously from the top surface side of the n-type epitaxial layer 5 toward the bottom surface side thereof.

In this embodiment, the n-type epitaxial layer 5 in the element region 2 has a property that the n-type impurity concentration in the n-type epitaxial layer 5 increases linearly (straight) from the top surface side of the n-type epitaxial layer 5 toward the bottom surface side thereof. Further, the n-type epitaxial layer 5 in the element region 2 may have a property that the n-type impurity concentration in the n-type epitaxial layer 5 increases curvilinearly from the top surface side of the n-type epitaxial layer 5 toward the bottom surface side thereof.

From the viewpoint of increasing the breakdown voltage of a parasitic pn diode formed by the p-type semiconductor substrate 4 and a region of the n-type epitaxial layer 5 near the p-type semiconductor substrate 4, it is desirable that the minimum value of the n-type impurity concentration in the n-type epitaxial layer 5 is 5×10¹⁴ cm⁻³ or more, and the maximum value of the n-type impurity concentration in the n-type epitaxial layer 5 is 1×10¹⁷ cm⁻³ or less.

Further, from the above viewpoint, it is desirable that the average value of the n-type impurity concentration in the n-type epitaxial layer 5 or the median value between the minimum value and the maximum value is 1×10¹⁵ cm⁻³ or more and 1×10¹⁶ cm⁻³ or less.

In this embodiment, the thickness of the n-type epitaxial layer 5 is 10 μm. The minimum value of the n-type impurity concentration in the n-type epitaxial layer 5 is 1×10¹⁵ cm⁻³, and the maximum value of the n-type impurity concentration in the n-type epitaxial layer 5 is 1×10¹⁶ cm⁻³. The average value of the n-type impurity concentration in the n-type epitaxial layer 5 or the median value between the minimum value and the maximum value is 5×10¹⁵ cm⁻³.

A method of manufacturing the semiconductor device 1A according to the second embodiment is substantially the same as the method of manufacturing the semiconductor device 1 according to the first embodiment. However, in the epitaxial growth process in the above-described step of FIG. 4A, the addition amount of the n-type impurities is set such that the n-type impurity concentration gradually decreases as the n-type semiconductor layer grows.

Also in the semiconductor device 1A according to the second embodiment, similarly to the semiconductor device 1 according to the first embodiment, it is possible to increase the element breakdown voltage of the DMOS transistor formed in the element region.

Although the case where the present disclosure is applied to the n-channel DMOS transistor has been described above, the present disclosure can also be applied to a p-channel DMOS transistor. In the p-channel DMOS transistor, for example, an n-type well region and a p-type drain region are formed at an interval in the surface layer portion of the n-type epitaxial layer 5 of FIG. 2 or FIG. 5. A p-type source region is formed in the surface layer portion of the n-type well region. A p⁺-type source contact region having a p-type impurity concentration higher than that of the p-type source region is formed in the surface layer portion of the p-type source region.

A p⁺-type drain contact region having a p-type impurity concentration higher than that of the p-type drain region is formed in the surface layer portion of the p-type drain region. A region between the p-type drain region and the p-type source region in the surface layer portion of the n-type epitaxial layer 5 is a channel region.

Various changes in design can be made to the present disclosure within the scope of the matters described in the claims.

The following noted features can be extracted from the description of the present disclosure and the drawings.

### [Supplementary Note 1-1]

A semiconductor device including:
a base (3) including a p-type substrate (4), an n-type semiconductor layer (5) formed on the p-type substrate (4), and an element region (2) having a transistor (40) provided with a source region (16) and a drain region (13A, 13B), which is formed at an interval in the surface layer portion of the n-type semiconductor layer (5); and
a p-type element isolation region (8) formed in the surface layer portion of the base (3) so as to partition the element region (2), and having an endless shape in a plan view,
wherein the n-type semiconductor layer (5) in the element region (2) has a property that an n-type impurity concentration increases stepwise or continuously from the surface of the n-type semiconductor layer (5) toward the p-type substrate (4) over the entire region along the surface of the p-type substrate (4).

### [Supplementary Note 1-2]

The semiconductor device of Supplementary Note 1-1, wherein the n-type semiconductor layer (5) in the element region (2) has a property that the n-type impurity concentration increases stepwise from the surface of the n-type semiconductor layer (5) toward the p-type substrate (4) over the entire region along the surface of the p-type substrate (4),
wherein the n-type semiconductor layer (5) in the element region (2) includes a first region (6) of a lower side, which is in contact with the p-type substrate (4), and a second region (7) of an upper side, which is arranged on the first region (6), and
wherein the n-type impurity concentration of the first region (6) is higher than the n-type impurity concentration of the second region (7).

### [Supplementary Note 1-3]

The semiconductor device of Supplementary Note 1-2, wherein the first region (6) covers the entire upper surface of the element region (2) in the p-type substrate (4).

### [Supplementary Note 1-4]

The semiconductor device of Supplementary Note 1-2, wherein the outer peripheral surface of the first region (6) is in contact with the inner peripheral surface of the p-type element isolation region (8).

### [Supplementary Note 1-5]

The semiconductor device of any one of Supplementary Notes 1-2 to 1-4, wherein the n-type impurity concentration of the first region (6) is 3×10¹⁵ cm⁻³ or more and 1×10¹⁷ cm⁻³ or less.

### [Supplementary Note 1-6]

The semiconductor device of Supplementary Note 1-5, wherein the n-type impurity concentration of the second region (7) is 5×10¹⁴ cm⁻³ or more and 3×10¹⁵ cm⁻³ or less.

### [Supplementary Note 1-7]

The semiconductor device of any one of Supplementary Notes 1-2 to 1-6, wherein the thickness of the first region (6) is 3 μm or more.

### [Supplementary Note 1-8]

The semiconductor device of any one of Supplementary Notes 1-2 to 1-6, wherein the thickness of the first region (6) is 4 μm or more.

### [Supplementary Note 1-9]

The semiconductor device of any one of Supplementary Notes 1-2 to 1-6, wherein the thickness of the first region (6) is 3/10 or more of the thickness of the n-type semiconductor layer (5).

### [Supplementary Note 1-10]

The semiconductor device of any one of Supplementary Notes 1-2 to 1-6, wherein the thickness of the first region (6) is ⅖ or more of the thickness of the n-type semiconductor layer (5).

### [Supplementary Note 1-11]

The semiconductor device of Supplementary Note 1-1, wherein the n-type semiconductor layer (5) in the element region (2) has a property that the n-type impurity concentration increases continuously from the surface of the n-type semiconductor layer (5) toward the p-type substrate (4) over the entire region along the surface of the p-type substrate (4), and wherein the minimum value of the n-type impurity concentration of the n-type semiconductor layer (5) in the element region (2) is 5×10¹⁴ cm⁻³ or more and the maximum value of the n-type impurity concentration of the n-type semiconductor layer (5) in the element region (2) is 1×10¹⁷ cm⁻³ or less.

### [Supplementary Note 1-12]

The semiconductor device of Supplementary Note 1-1, wherein the n-type semiconductor layer (5) in the element region (2) has a property that the n-type impurity concentration increases continuously from the surface of the n-type semiconductor layer (5) toward the p-type substrate (4) over the entire region along the surface of the p-type substrate (4), and wherein the average value of the n-type impurity concentration of the n-type semiconductor layer (5) in the element region (2) or the median value between the minimum value and the maximum value of the n-type impurity concentration is 1×10¹⁵ cm⁻³ or more and 1×10¹⁶ cm⁻³ or less.

### [Supplementary Note 1-13]

The semiconductor device of any one of Supplementary Notes 1-1 to 1-12, wherein the transistor (40) includes:
a p-type region (15) formed in the surface layer portion of the n-type semiconductor layer (5);
one of the source region (16) and the drain region (13A, 13B), which is formed in the surface layer portion of the p-type region (15); and
the other of the source region (16) and the drain region (13A, 13B), which is formed in the surface layer portion of the n-type semiconductor layer (5) with being spaced apart from the p-type region.

### [Supplementary Note 1-14]

The semiconductor device of Supplementary Note 1-13, wherein the transistor (40) further includes:
a gate insulating film (18) formed to cover a channel region (20) between the source region (16) and the drain region (13A, 13B); and
a gate electrode (19) formed on the gate insulating film (18) and facing the channel region (20) via the gate insulating film (18).

### [Supplementary Note 1-15]

A method of manufacturing a semiconductor device, including:
forming a base including a p-type substrate (4) and an n-type semiconductor layer (5) formed on the p-type substrate (4) and having a property that the n-type impurity concentration increases stepwise or continuously from the surface of the n-type semiconductor layer (5) toward the p-type substrate (4) by allowing a semiconductor to epitaxially grow while adding n-type impurities to the surface of the p-type substrate (4);
forming an element region (2), which is surrounded by a p-type element isolation region (8), in the base by forming the p-type element isolation region (8), which reaches the p-type substrate (4) from the surface of the n-type semiconductor layer (5) and has an endless shape in a plan view, in the base (3); and
forming a source region (16) and a drain region (13A, 13B) at an interval in the surface layer portion of the n-type semiconductor layer (5) in the element region (2).

### [Supplementary Note 1-16]

The method of Supplementary Note 1-15, wherein the forming the source region (16) and the drain region (13A, 13B) includes:
forming a p-type region (15) in the surface layer portion of the n-type semiconductor layer (5);
forming one of the source region (16) and the drain region (13A, 13B) in the surface layer portion of the p-type region (15); and
forming the other of the source region (16) and the drain region (13A, 13B) in the surface layer portion of the n-type semiconductor layer (5) with being spaced apart from the p-type region (15).

### [Supplementary Note 1-17]

The method of Supplementary Note 1-15 or 1-16, further including:
forming a gate insulating film (18) in the surface of the n-type semiconductor layer (5) so as to cover a channel region (20) between the source region (16) and the drain region (13A, 13B); and
forming a gate electrode (19), which faces the channel region (20) via the gate insulating film (18), on the gate insulating film (18).

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device comprising:
a base including a p-type substrate, an n-type semiconductor layer formed on the p-type substrate, and an element region having a transistor provided with a source region and a drain region, which are formed at an interval in a surface layer portion of the n-type semiconductor layer; and
a p-type element isolation region formed in a surface layer portion of the base so as to partition the element region, and having an endless shape in a plan view,
wherein the n-type semiconductor layer in the element region has a property that an n-type impurity concentration increases stepwise or continuously from a surface of the n-type semiconductor layer toward the p-type substrate over an entire region along a surface of the p-type substrate.

2. The semiconductor device of claim 1, wherein the n-type semiconductor layer in the element region has a property that the n-type impurity concentration increases stepwise from the surface of the n-type semiconductor layer toward the p-type substrate over the entire region along the surface of the p-type substrate,
wherein the n-type semiconductor layer in the element region includes a first region of a lower side, which is in contact with the p-type substrate, and a second region of an upper side, which is arranged on the first region, and
wherein the n-type impurity concentration of the first region is higher than the n-type impurity concentration of the second region.

3. The semiconductor device of claim 2, wherein the first region covers an entire upper surface of the element region in the p-type substrate.

4. The semiconductor device of claim 2, wherein an outer peripheral surface of the first region is in contact with an inner peripheral surface of the p-type element isolation region.

5. The semiconductor device of claim 2, wherein the n-type impurity concentration of the first region is 3×10¹⁵ cm⁻³ or more and 1×10¹⁷ cm⁻³ or less.

6. The semiconductor device of claim 5, wherein the n-type impurity concentration of the second region is 5×10¹⁴ cm⁻³ or more and 3×10¹⁵ cm⁻³ or less.

7. The semiconductor device of claim 2, wherein a thickness of the first region is 3 μm or more.

8. The semiconductor device of claim 2, wherein a thickness of the first region is 4 μm or more.

9. The semiconductor device of claim 2, wherein a thickness of the first region is 3/10 or more of the thickness of the n-type semiconductor layer.

10. The semiconductor device of claim 2, wherein a thickness of the first region is ⅖ or more of a thickness of the n-type semiconductor layer.

11. The semiconductor device of claim 1, wherein the n-type semiconductor layer in the element region has a property that the n-type impurity concentration increases continuously from the surface of the n-type semiconductor layer toward the p-type substrate over the entire region along the surface of the p-type substrate, and
wherein a minimum value of the n-type impurity concentration of the n-type semiconductor layer in the element region is 5×10¹⁴ cm⁻³ or more and a maximum value of the n-type impurity concentration of the n-type semiconductor layer in the element region is 1×10¹⁷ cm⁻³ or less.

12. The semiconductor device of claim 1, wherein the n-type semiconductor layer in the element region has a property that the n-type impurity concentration increases continuously from the surface of the n-type semiconductor layer toward the p-type substrate over the entire region along the surface of the p-type substrate, and
wherein an average value of the n-type impurity concentration of the n-type semiconductor layer in the element region or a median value between a minimum value and a maximum value of the n-type impurity concentration is 1×10¹⁵ cm⁻³ or more and 1×10¹⁶ cm⁻³ or less.

13. The semiconductor device of claim 1, wherein the transistor includes:
a p-type region formed in the surface layer portion of the n-type semiconductor layer;
one of the source region and the drain region, which is formed in the surface layer portion of the p-type region; and
the other of the source region and the drain region, which is formed in the surface layer portion of the n-type semiconductor layer by being spaced apart from the p-type region.

14. The semiconductor device of claim 13, wherein the transistor further includes:
a gate insulating film formed to cover a channel region between the source region and the drain region; and
a gate electrode formed on the gate insulating film and facing the channel region via the gate insulating film.

15. A method of manufacturing a semiconductor device, comprising:
forming a base including a p-type substrate and an n-type semiconductor layer formed on the p-type substrate and having a property that an n-type impurity concentration increases stepwise or continuously from a surface of the n-type semiconductor layer toward the p-type substrate to epitaxially grow a semiconductor while adding n-type impurities to a surface of the p-type substrate;
forming an element region, which is surrounded by a p-type element isolation region, in the base by forming the p-type element isolation region, which reaches the p-type substrate from the surface of the n-type semiconductor layer and has an endless shape in a plan view, in the base; and
forming a source region and a drain region at an interval in a surface layer portion of the n-type semiconductor layer in the element region.

16. The method of claim 15, wherein the forming the source region and the drain region includes:
forming a p-type region in the surface layer portion of the n-type semiconductor layer;
forming one of the source region and the drain region in a surface layer portion of the p-type region; and
forming the other of the source region and the drain region in the surface layer portion of the n-type semiconductor layer by being spaced apart from the p-type region.

17. The method of claim 15, further comprising:
forming a gate insulating film in the surface of the n-type semiconductor layer so as to cover a channel region between the source region and the drain region; and
forming a gate electrode, which faces the channel region via the gate insulating film, on the gate insulating film.
